(19) United States
(12) Patent Application Publication
(10) Pub. No.: US 2010/0133419 A1
(43) Pub. Date: Jun. 3, 2010

(54) ELECTRONIC ELEMENT WAFER MODULE AND METHOD FOR MANUFACTURING SAME, ELECTRONIC ELEMENT MODULE, OPTICAL ELEMENT WAFER MODULE AND METHOD FOR MANUFACTURING SAME, AND ELECTRONIC INFORMATION DEVICE

(75) Inventor: Aiji SUETAKE, Osaka-shi (JP)

Correspondence Address: NIXON & VANDERHYE, PC, 901 NORTH GLEBE ROAD, 11TH FLOOR, ARLINGTON, VA, 22203, US

(73) Assignee: SHARP KABUSHIKI KAISHA, Osaka (JP)

(21) Appl. No.: 12/628,607

(22) Filed: Dec. 1, 2009

(30) Foreign Application Priority Data
Dec. 1, 2008 (JP) 2008-306876

(51) Int. Cl. H01L 27/00; B05D 5/06; B32B 37/12; B29D 11/00; C23C 14/28

(52) U.S. Cl. 250/208.1; 427/58; 156/155; 216/24; 427/595

(57) ABSTRACT

A method for manufacturing an electronic element wafer module is provided, the method comprising: a protective resin film forming step of forming a protective resin film on only light openings of the plurality of wafer-shaped optical elements; a light shielding film forming step of filming a light shielding film on an area except for the light openings or an entire area including the light openings; and an optical aperture forming step of removing the protective resin film, or removing the protective resin film and a light shielding film material on the protective resin film, to form an optical aperture structure by the light shielding film at the light openings.

This nonprovisional application claims priority under 35 U.S.C. §119(a) to Patent Application No. 2008-306876 filed in Japan on Dec. 1, 2008, the entire contents of which are hereby incorporated by reference.

### BACKGROUND OF THE INVENTION

1. Field of the Invention

The present invention relates to an electronic element wafer module with an optical aperture structure and a method for manufacturing the electronic element wafer module; an optical element wafer module used for the electrical element wafer module and a method for manufacturing the optical element wafer module; an electronic element module individualized by simultaneously cutting the electronic element wafer module; and an electronic information device, such as a digital camera (e.g., a digital video camera or a digital still camera), an image input camera (e.g., a monitoring camera), a scanner, a facsimile machine, a television telephone apparatus and a camera-equipped cell phone device, including the electronic element module as an image input device used in an image capturing section thereof.

2. Description of the Related Art

Reference 1 proposes a lens aperture structure with a light shielding film above a lens, which is used for a conventional camera module.

FIG. 17 is a longitudinal cross sectional view illustrating an exemplary essential structure of a remote control light receiving module, which is one of conventional optical function modules, disclosed in Reference 1.

As illustrated in FIG. 17, a conventional remote control light receiving module 100 has a structure including a lead frame 101, an infrared ray light receiving element 102 thereon, a signal processing circuit 103 for processing output signals therefrom, and a transparent resin 104 for molding installed and connected chip parts required for the signal processing circuit 103. Further, a light shielding film 106 is formed on a plane surface portion of the transparent resin 104 except for on a light receiving lens portion 105 thereon.

The lead frame 101 is constituted of a metal plate material, including any of Fe, Ni, Cu or an alloy thereof, as a main component. A surface of the lead frame 101 is coated with a film of Ag. Regarding the shape of the lead frame 101, the overall mold is supported by a terminal group 107 protruded externally, and the lead frame 101 is constituted of several separate portions within the molded inside to electrically connect the infrared ray light receiving element 102 and the signal processing circuit 103.

The infrared ray light receiving element 102 is positioned such that the light receiving lens portion 105 is aligned with the center of the infrared ray light receiving element 102. Regarding the size of the infrared ray light receiving element 102, an element 2 mm square or less can also be used depending on a light focusing capability of the light receiving lens portion.

The signal processing circuit 103 has functions including conversion of input electric signals (current) into voltage, amplification of the voltage, filtration of noise signal components other than a remote control signal, detection of the voltage, and rectification of the voltage.

The transparent resin 104 is molded in such a manner to cover the signal processing circuit 103 and the infrared ray light receiving element 102 installed on the lead frame 101, and at the same time, the light receiving lens portion 105 is formed on a front surface side of the transparent resin 104.

The light shielding film 106 is formed on a plane front surface portion, except for the light receiving lens portion 105, of the surface into which infrared rays enter. A black epoxy resin for example, can be used as the material. It is also possible to use ABS resin, PP resin or PC resin.

In the conventional remote control light receiving module 100, the required chip parts, infrared ray or visible-light light receiving element (infrared ray light receiving element 102) and signal processing integrated circuit (signal processing circuit 103) are installed on a substrate. Subsequently, the light-permeable transparent resin 104 is molded over them, and the light shielding film 106 and an electromagnetic shielding film thereon (not shown), which reduces electromagnetic noise, is applied on the front surface area other than the light receiving lens portion 105.

The light shielding film 106 and the electromagnetic shielding film can be attached specifically by the application of paint or adhesion of a sheet of an adhesive layer. A window size of the light receiving lens portion 105 can be exactly formed by the borderline between a non-plane surface portion and a plane surface portion of the light receiving portion, and it can be defined, for example, as an end of the plane portion, that is, the size of the external shape measure of the module. Additionally, for example, Al foil, a non-metal based sheet with an Al foil, or a sheet of a CU foil with an adhesive layer on the back surface is available at a low price, and can be used as an electric shield material without difficulty.

Reference 1: Japanese Laid-Open Publication No. 2002-246613

### SUMMARY OF THE INVENTION

In the above conventional remote control light receiving module 100, the positional accuracy of the light shielding film is not regarded to be as important as the positional accuracy of a camera module. Further, elements are molded inside and the light shielding film 106 and the electromagnetic shielding film are applied or adhered as a sheet thereabove. As a result, if the positional accuracy of the light shielding film is poor, even the normally-functioning infrared ray light receiving element 102 and signal processing circuit 103 will start to function poorly. This leads to an extremely poor manufacturing efficiency.

Furthermore, in the above conventional remote control light receiving module 100, the positioning of the internal elements is not accurate, and particularly, the method for manufacturing the remote control light receiving module 100 cannot be applied at all in terms of its accuracy for a camera module that requires a strict positional relationship between the light receiving portion 105 and the infrared ray light receiving element 102.

The present invention is intended to solve the conventional problems described above. The objective of the present invention is to provide an electronic element wafer module, which achieves a high positional accuracy of electronic elements and a high positioning accuracy between the electronic elements and an optical aperture structure of an optical element and a light shielding film, and to achieve a high manufacturing efficiency, compared to an optical function module with the conventional module structure, and a method for manufacturing the electronic element wafer module; an optical element wafer module used for the electronic element wafer module and a method for manufacturing the optical element wafer module; an electronic element module individualized by simultaneously cutting the electronic element wafer module; and an electronic information device, such as a camera-equipped cell phone device, including the electronic element module as an image input device used in an image capturing section thereof.

A method for manufacturing an electronic element wafer module according to the present invention is provided, in which a plurality of optical elements of at least one wafer shape are positioned on an electronic element wafer with a plurality of electronic elements formed therein, such that the plurality of optical elements face the plurality of respective electronic elements, the method including: a protective resin film forming step of forming a protective resin film on only light openings of the plurality of wafer-shaped optical elements; a light shielding film forming step of filming a light shielding film on an area except for the light openings or an entire area including the light openings; and an optical aperture forming step of removing the protective resin film, or removing the protective resin film and a light shielding film material on the protective resin film, to form an optical aperture structure in the light shielding film at the light openings, thereby achieving the objective described above.

Preferably, in a method for manufacturing an electronic element wafer module according to the present invention, the optical aperture forming step includes: an adhesive tape adhering step of adhering an adhesive tape on the light shielding film on the protective resin film; and an adhesive tape peeling step of peeling off the adhesive tape together with the protective resin film and the light shielding film on the protective resin film.

Still preferably, in a method for manufacturing an electronic element wafer module according to the present invention, the optical aperture forming step includes a protective resin film removing step of dissolving and removing the protective resin film with a solution.

Still preferably, in a method for manufacturing an electronic element wafer module according to the present invention, the protective resin film is either a protective resin film having viscosity lower than viscosity of the light shielding film or a soluble protective resin film.

Still preferably, in a method for manufacturing an electronic element wafer module according to the present invention, in the protective resin film forming step, a material of the protective resin film to be formed is discharged by a dispenser.

Still preferably, in a method for manufacturing an electronic element wafer module according to the present invention, in the protective resin film forming step, an etching process is performed using a photoresist film, which is patterned to a predetermined shape, as a mask, to leave the protective resin film on only the light openings.

Still preferably, in a method for manufacturing an electronic element wafer module according to the present invention, a material capable of being dissolved with water or ethanol as a predetermined solution and being removed by washing with water is used for the soluble protective resin film.

Still preferably, in a method for manufacturing an electronic element wafer module according to the present invention, a film thickness/a plan view diameter is set between 0.5 and 1.0 as the aspect ratio of the protective resin film.

Still preferably, in a method for manufacturing an electronic element wafer module according to the present invention, the light shielding film uses, as a material, any of acrylic resin, epoxy resin, ABS resin, PP resin and PC resin.

Still preferably, in a method for manufacturing an electronic element wafer module according to the present invention, the material of the light shielding film contains carbon.

Still preferably, in a method for manufacturing an electronic element wafer module according to the present invention, the material of the light shielding film is either UV curing resin or thermosetting resin.

Still preferably, in a method for manufacturing an electronic element wafer module according to the present invention, a transparent support substrate is positioned on the electronic element wafer, and the plurality of optical elements of at least one wafer shape are positioned on the transparent support substrate.

Still preferably, in a method for manufacturing an electronic element wafer module according to the present invention, the plurality of wafer-shaped optical elements are adhered on the electronic element wafer with the plurality of electronic elements formed therein, and subsequently, the protective resin film forming step, the light shielding film forming step, and the optical aperture forming step are performed.

Still preferably, in a method for manufacturing an electronic element wafer module according to the present invention, an optical element wafer module is formed, in which the plurality of optical element wafers with the optical elements arranged in two dimensions therein are laminated to one another, and subsequently, the protective resin film forming step, the light shielding film forming step, and the optical aperture forming step are performed for the optical element wafer module, and further, the optical element wafer module, on which the optical aperture structure is formed, is adhered on the electronic element wafer with the plurality of electronic elements formed therein.

Still preferably, in a method for manufacturing an electronic element wafer module according to the present invention, the protective resin film forming step, the light shielding film forming step, and the optical aperture forming step are performed for the optical element wafer on which the plurality of optical elements are arranged in two dimensions, and subsequently, in such a manner that the optical element wafer is arranged to the upper most position, the plurality of optical element wafers, on which the plurality of optical elements are arranged in two dimensions, are laminated to form an optical element wafer module, and further, the optical element wafer module is adhered on the electronic element wafer with the plurality of electronic elements formed therein.

A method for manufacturing an optical element wafer module according to the present invention is provided, on which a plurality of optical element wafers with a plurality of optical elements arranged in two dimensions therein are laminated, the method including: a protective resin film forming step of forming a protective resin film on only light openings of the plurality of wafer-shaped optical elements; a light shielding film forming step of filming a light shielding film on an area except for the light openings or an entire area including the light openings; and an optical aperture forming step of removing the protective resin film, or removing the protective resin film and a light shielding film material on the protective resin film, to form an optical aperture structure in the light shielding film at the light openings, thereby achieving the objective described above.

Preferably, in a method for manufacturing an optical element wafer module according to the present invention, the optical aperture forming step includes: an adhesive tape adhering step of adhering an adhesive tape on the light shielding film on the protective resin film; and an adhesive tape peeling step of peeling off the adhesive tape together with the protective resin film and the light shielding film on the protective resin film to form optical apertures at the respective light openings.

Still preferably, in a method for manufacturing an optical element wafer module according to the present invention, the optical aperture forming step includes a protective resin film removing step of dissolving and removing the protective resin film with a solution.

Still preferably, in a method for manufacturing an optical element wafer module according to the present invention, the protective resin film forming step, the light shielding film forming step, and the optical aperture forming step are performed for the optical element wafer module, in which the plurality of optical element wafers with the plurality of optical elements formed in two dimensions therein are laminated.

Still preferably, in a method for manufacturing an optical element wafer module according to the present invention, the protective resin film forming step, the light shielding film forming step, and the optical aperture forming step are performed for the optical element wafer with the plurality of optical elements formed in two dimensions therein, and subsequently, in such a manner that the optical element wafer is arranged to the upper most position, the plurality of optical element wafers, on which the plurality of optical elements are arranged in two dimensions, are laminated to form an optical element wafer module.

An electronic element wafer module according to the present invention is manufactured by any of the methods for manufacturing the electronic element wafer module according to the present invention, where the optical element is either a lens or a prism, and the electronic element is an image capturing element including a plurality of light receiving sections for performing a photoelectric conversion on and capturing an image of image light from a subject, thereby achieving the objective described above.

An electronic element wafer module according to the present invention is manufactured by any of the methods for manufacturing the electronic element wafer module according to the present invention, where the optical element is an optical function element for directing output light straight to be output and refracting and guiding incident light in a predetermined direction, and the electronic element is a light emitting element for emitting output light and a light receiving element for receiving incident light, thereby achieving the objective described above.

An electronic element module according to the present invention is provided, which is cut and individualized from the electronic element wafer module according to the present invention, for every one or the plurality of electronic element modules, thereby achieving the objective described above.

An optical element wafer module according to the present invention is manufactured by any of the methods for manufacturing the optical element wafer module according to the present invention, where the optical element is either a lens or a prism, thereby achieving the objective described above.

An optical element wafer module according to the present invention is manufactured by any of the methods for manufacturing the optical element wafer module according to the present invention, where the optical element is an optical function element for directing output light straight to be output and refracting and guiding incident light in a predetermined direction, thereby achieving the objective described above.

An electronic information device according to the present invention includes the electronic element module according to the present invention as an image input device in an image capturing section, thereby achieving the objective described above.

The functions of the present invention having the structures described above will be described hereinafter.

The present invention includes: a protective resin film forming step for forming a protective resin film on only light openings of the plurality of wafer-shaped optical elements; a light shielding film forming step of filming a light shielding film on an area except for the light openings or an entire area including the light openings; and an optical aperture forming step of removing the protective resin film, or removing the protective resin film and a light shielding film material on the protective resin film to form an optical aperture structure by the light shielding film at the light openings.

As a result, the protective resin film is discharged with a high positional accuracy by a dispenser, and the protective resin film is removed after the light shielding film is formed based on the discharge. Thus, compared to an optical function module with the conventional mold structure, it becomes possible to achieve a high positional accuracy of the internal electronic elements and a high positioning accuracy between the internal electronic elements and the optical aperture structure of the optical element and the light shielding film, and a high manufacturing efficiency is achieved.

According to the present invention with the structure described above, by providing a protective resin film 7 or 7A with a high positional accuracy, it becomes possible to achieve a high positional accuracy of the internal elements and a high positioning accuracy between the internal elements and the optical aperture structure of the optical element and the light shielding film, and a high manufacturing efficiency is achieved, compared to the optical function module with the conventional mold structure.

Further, a drastic improvement on the productivity and a drastic cut in the cost can be achieved by eliminating the molding after the manufacturing of the optical element wafer module as opposed to the conventional technique, and by the entire shielding of the upper surface of the optical element wafer module by the light shielding film and the simultaneous manufacturing of a large number of the optical aperture structures.

Further, a drastic reduction of the accumulative cost can be achieved by securing a high positional accuracy of the discharging of a light shielding film material by ink jet or the like and by the use of a device with fast signal processing.

Further, by precisely positioning the electronic elements and the optical elements with a high positional accuracy, precisely positioning the optical aperture structure with a certain accuracy together with the light shielding function with respect to the electronic elements and the light shielding film, and manufacturing a mask and the light shielding film at a high speed, it becomes possible to easily remove the mask and to perform the manufacturing with a simple process and at a low cost.

These and other advantages of the present invention will become apparent to those skilled in the art upon reading and understanding the following detailed description with reference to the accompanying figures.

### BRIEF DESCRIPTION OF THE DRAWINGS

FIG. 1 is a longitudinal cross sectional view illustrating an exemplary essential part structure of a sensor wafer module according to Embodiment 1 of the present invention.

FIG. 2 is a longitudinal cross sectional view illustrating an exemplary essential part structure of a sensor module formed by simultaneously cutting and individualizing the sensor wafer module of FIG. 1.

FIGS. 3(a) to 3(d) are each an essential part longitudinal cross sectional view of each manufacturing step (part I) for describing a method for manufacturing the sensor wafer module of FIG. 1.

FIGS. 4(a) to 4(c) are each an essential part longitudinal cross sectional view of each manufacturing step (part II) for describing a method for manufacturing the sensor wafer module of FIG. 1.

FIGS. 5(a) to 5(d) are each an essential part longitudinal cross sectional view of each manufacturing step (part I) for describing another example of the method for manufacturing the sensor wafer module of FIG. 1.

FIGS. 6(a) to 6(d) are each an essential part longitudinal cross sectional view of each manufacturing step (part II) for describing another example of the method for manufacturing the sensor wafer module of FIG. 1.

FIG. 7 is a longitudinal cross sectional view illustrating an exemplary essential part structure of a lens wafer module according to Embodiment 2 of the present invention.

FIGS. 8(a) to 8(d) are each an essential part longitudinal cross sectional view of each manufacturing step (part I) for describing a method for manufacturing a sensor wafer module of FIG. 7.

FIGS. 9(a) to 9(o) are each an essential part longitudinal cross sectional view of each manufacturing step (part II) for describing the method for manufacturing the sensor wafer module of FIG. 7.

FIGS. 10(a) to 10(d) are each an essential part longitudinal cross sectional view of each manufacturing step (part I) for describing another example of the method for manufacturing the sensor wafer module of FIG. 7.

FIGS. 11(a) to 11(d) are each an essential part longitudinal cross sectional view of each manufacturing step (part II) for describing another example of the method for manufacturing the sensor wafer module of FIG. 7.

FIGS. 12(a) to 12(d) are each an essential part longitudinal cross sectional view of each manufacturing step (part I) for describing a different example of the method for manufacturing the lens wafer module of FIG. 7.

FIGS. 13(a) to 13(d) are each an essential part longitudinal cross sectional view of each manufacturing step (part II) for describing a different example of the method for manufacturing the lens wafer module of FIG. 7.

FIGS. 14(a) to 14(d) are each an essential part longitudinal cross sectional view of each manufacturing step (part I) for describing a further different example of the method for manufacturing the lens wafer module of FIG. 7.

FIGS. 15(a) to 15(e) are each an essential part longitudinal cross sectional view of each manufacturing step (part II) for describing a further different example of the method for manufacturing the lens wafer module of FIG. 7.

FIG. 16 is a block diagram schematically illustrating an exemplary schematic structure of an electronic information device as Embodiment 4 of the present invention, including the sensor module 10 according to any of Embodiments 1 to 3 of the present invention used in an image capturing section thereof.

FIG. 17 is a longitudinal cross sectional view illustrating an exemplary essential structure of a remote control light receiving module, which is one of conventional optical function modules, disclosed in Reference 1.

1 sensor wafer (electronic element wafer)
1a image capturing element
1b through hole
1c solder ball
2 resin adhesion layer
3 glass plate (transparent support substrate)
4, 4A lens wafer module (optical element wafer module)
4a light opening
41 aberration correction lens plate
42 diffusion lens plate
43 light focusing lens plate
5 light shielding film
5a light shielding film material
6a lens adhesion layer
7 low-viscosity protective resin film
7A soluble protective resin film
8 adhesive tape (peeling tape)
10 sensor module (electronic element module)
11 sensor wafer module (electronic element wafer module)
TSV module
91 solid-state image capturing apparatus
92 memory section
93 display section
94 communication section
95 image output section

### DESCRIPTION OF THE PREFERRED EMBODIMENTS

Hereinafter, Embodiment 1, in which an electronic element wafer module with an optical aperture structure according to the present invention and a method for manufacturing thereof are applied to a sensor wafer module and a method for manufacturing thereof, Embodiments 2 and 3, in which an optical element wafer module according to the present invention used for the electronic element wafer module and a method for manufacturing thereof are applied to a lens wafer module and a method for manufacturing thereof, and Embodiment 4, in which an electronic information device, such as a camera-equipped cell phone device, including a sensor module (camera module) as an image input device used in an image capturing section thereof, the sensor module functioning as an electronic element module and individualized by simultaneously cutting a sensor wafer module as the electronic element wafer module, will be described in detail with reference to the accompanying figures.

### Embodiment 1

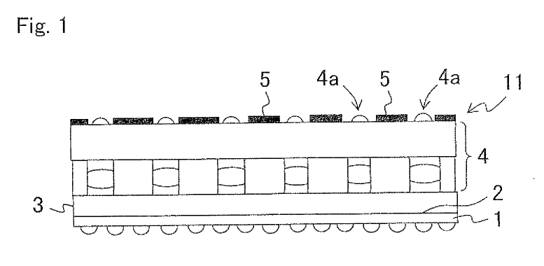

FIG. 1 is a longitudinal cross sectional view illustrating an exemplary essential part structure of a sensor wafer module according to Embodiment 1 of the present invention.

In FIG. 1, a sensor wafer module 11 according to Embodiment 1 includes: a sensor wafer 1, in which an image capturing element is provided as an electronic element on a wafer surface, the image capturing element constituted of a plurality of light receiving sections as photoelectric conversion sections (photodiodes) respectively corresponding to a plurality of pixels, and a through hole is provided between a front surface and a back surface for electrical connection; a resin adhesion layer 2 formed in the periphery of the image capturing element of the sensor wafer 1; a glass plate 3 as a cover glass for covering the image capturing element and the resin adhesion layer 2; a lens wafer module 4 provided on the glass plate 3 and including one or more lens plates laminated therein as an optical element for focusing incident light on the image capturing element; and light shielding films 5 with an optical aperture structure, formed on a plane surface area other than above light openings 4a for a plurality of respective lenses, of the lens wafer module 4.

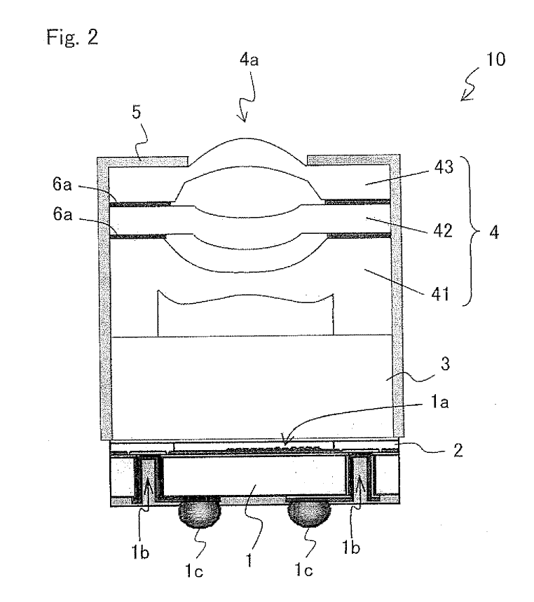

On the sensor wafer 1, the glass plate 3 and the lens wafer module 4 are adhered one above the other, in this order, with alignment to each other, by resin adhesion layer 2 and a lens adhesion layer (lens adhesion layer 6a in FIG. 2). The sensor wafer module 11 according to Embodiment 1 is formed by laminating the sensor wafer 1, resin adhesion layer 2, glass plate 3 and lens wafer module 4. The sensor wafer module 11 at the wafer level is simultaneously cut and individualized, and subsequently a light shielding member is provided on side surfaces thereof, so that a sensor module (camera module) can be manufactured as a semiconductor chip. The sensor module can be structured, for example, as illustrated in FIG. 2. In addition, although described in detail later, the lens wafer module 4 and the light shielding film 5, which has an optical aperture structure formed on the plane surface area, constitute a lens wafer module 4A.

As illustrated in FIG. 2, in a sensor module 10, an image capturing element 1a (in which a plurality of light receiving sections are provided, constituting a plurality of pixels for each image capturing element) is arranged on a front surface side of the sensor wafer 1, the thickness of the sensor wafer 1 is between 100 and 200 μm, and a plurality of through holes 1b are provided penetrating from a back surface thereof to a front surface below a pad. The side wall and back surface side of the through hole are covered with an insulation film, and a wiring layer connected with a pad is formed through the through hole 1b to the back surface. A solder resist is formed on the wiring layer and the back surface, and the solder resist has a window on a portion where a solder ball 1c is formed on the wiring layer so that the solder ball 1c is formed to be exposed externally. Each layer of the sensor wafer 1 can be formed by various techniques employed for normal semiconductor processing, including photolithography, etching, soldering and CVD methods. After the cutting of the wafer, a sensor substrate (a sensor chip section functioning as an electronic element chip section) is formed with an element area in the center portion.

As illustrated in FIG. 2, the lens wafer module 4 is a transparent resin lens plate, and is constituted of a center portion, which is a lens area functioning as a lens, and a peripheral portion as a spacer section functioning as a spacer. The overall lens wafer module 4 is formed with the same resin material. The transparent resin lens plate is formed as follows. A lens resin material is inserted into an upper forming die and a lower forming die. The distance between the upper and lower forming dies is accurately controlled to a predetermined thickness. The lens resin is cured by a method such as ultraviolet (UV) curing or a thermal curing. Further, a thermal process is performed. Internal stress is released to stabilize a lens shape, and the transparent resin lens plate is formed. By this method, it becomes possible to form such a resin lens plate with a predetermined lens shape and a predetermined lens thickness.

The transparent resin lens plate as an optical element is constituted of an aberration correction lens plate 41, a diffusion lens plate 42, and a light focusing lens plate 43, and at least one plate is a light focusing lens plate. In the transparent resin lens plate, a lens area is provided at the center portion and peripheral portion is provided on the outer circumference side of the lens area as a spacer section with a predetermined thickness. Each spacer section with a predetermined thickness is provided on the outer circumference side of each of the lens plates that constitute the entire transparent resin lens plate, and the plurality of the spacer sections are laminated and arranged from the bottom in this order. The spacer section has a positioning function, and a positioning function section is constituted of tapered concave and convex portions or alignment marks.

The light shielding film 5 is provided as an optical aperture structure on a plane surface area other than on respective light openings 4a above the plurality of lenses. That is, a light shielding and electromagnetic noise reduction film is formed as the light shielding film 5 on the lens area above the image capturing element, without molding the electronic element module or image capturing element, to shield the area of the sensor module 10 except for above the light receiving section.

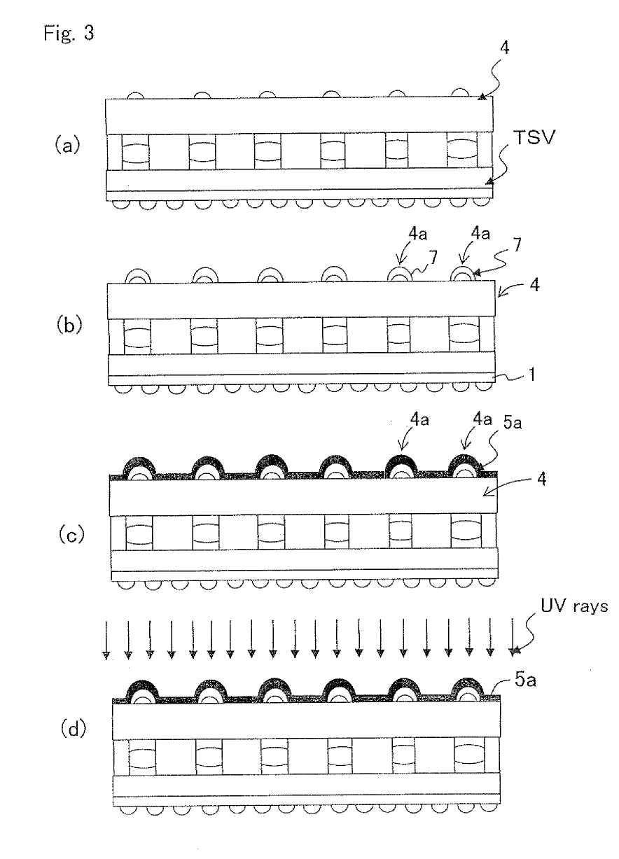

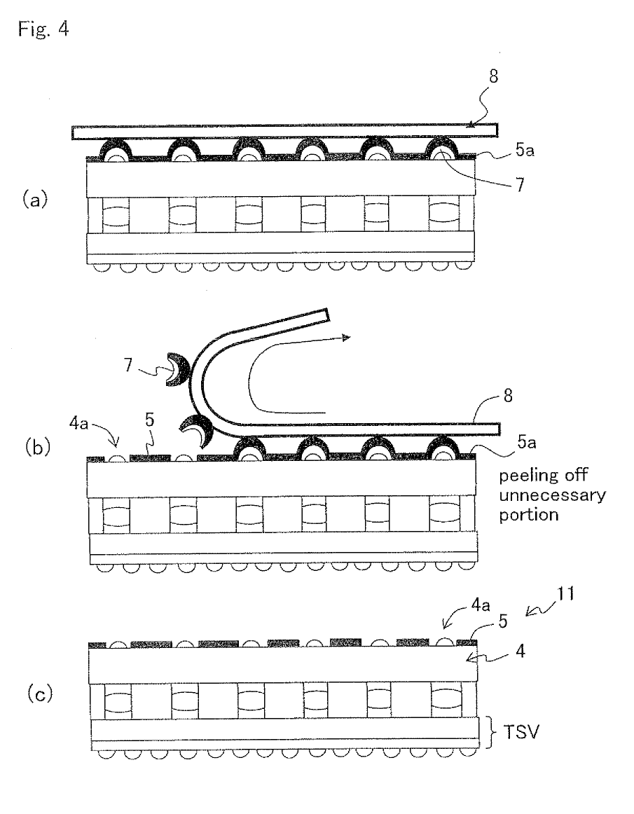

In summary, in the above structure, the glass plate 3 is provided as a transparent support substrate above the sensor wafer 1 with the plurality of image capturing elements formed thereon, and a wafer form of the plurality of lenses are arranged facing the respective image capturing elements on the glass plate 3. Hereinafter, a method for manufacturing the sensor wafer module 11 with the above structure will be described in detail with reference to FIGS. 3(a) to 3(d) and FIGS. 4(a) to 4(c).

First, a plurality of lens plates at the wafer level are laminated one above the other to form the lens wafer module 4, and the glass plate 3 is adhered to the sensor wafer 1 with the resin adhesion layer 2 one above the other to form a module TSV. Further, as illustrated in an adhering step of FIG. 3(a), the lens wafer module 4 is adhered on the module TSV with an alignment (positioning) such that the positions of the respective image capturing elements of the module TSV accurately correspond to the positions of the respective lenses of the lens wafer module 4.

Next, as illustrated in a protective resin forming step of FIG. 3(b), a low-viscosity, protective resin film 7 is discharged from and formed by a dispenser (ink jet) with a high positional accuracy, only on the light openings 4a of the plurality of wafer-shaped image capturing elements of the sensor wafer 1. The protective resin film 7 is formed by an etching process performed using a photoresist film, which is patterned to a predetermined shape, as a mask. As a result, the protective resin film 7 remains accurately on only each of the light openings 4a of the respective image capturing elements. Further, the material for the protective resin film 7 may have a low viscosity with respect to the lens material (transparent resin or glass) for the lens wafer module 4, such that, in a later step, an adhesive tape can be peeled off both easily and securely together with the protective resin film 7 and a light shielding film 5a thereon and further, the protective resin film 7 will not slip out of place or fall off from the lens surface.

Subsequently, as illustrated in a light shielding film forming step of FIG. 3(c), the light shielding material 5a is applied to cover the entire area including the light openings 4a of the plurality of wafer-shaped image capturing elements of the sensor wafer 1 for the formation of the light shielding material 5a.

Next, as illustrated in a UV irradiating step of FIG. 3(d), ultraviolet rays (UV) are irradiated onto the material of the light shielding film 5a, which is applied on the entire module, to be cured.

Further, as illustrated in a adhesive tape adhering step of FIG. 4(a), an adhesive tape 8 (peeling tape) is adhered on the light shielding material 5a on the protective resin film 7. In this case, the adhesive tape 8 is adhered to only the light shielding material 5a portion on the protective resin film 7 on the protruded lens surface (light opening 4a).

Further, as illustrated in an adhesive tape peeling step of FIG. 4(b), the adhesive tape 8 is peeled off together with the protective resin film 7 and the light shielding film material 5a on the protective resin film 7 to form an optical aperture, which is a circular shape a plan view, by the light shielding film 5 at the light opening 4a of the lens area as illustrated in FIG. 4(c).

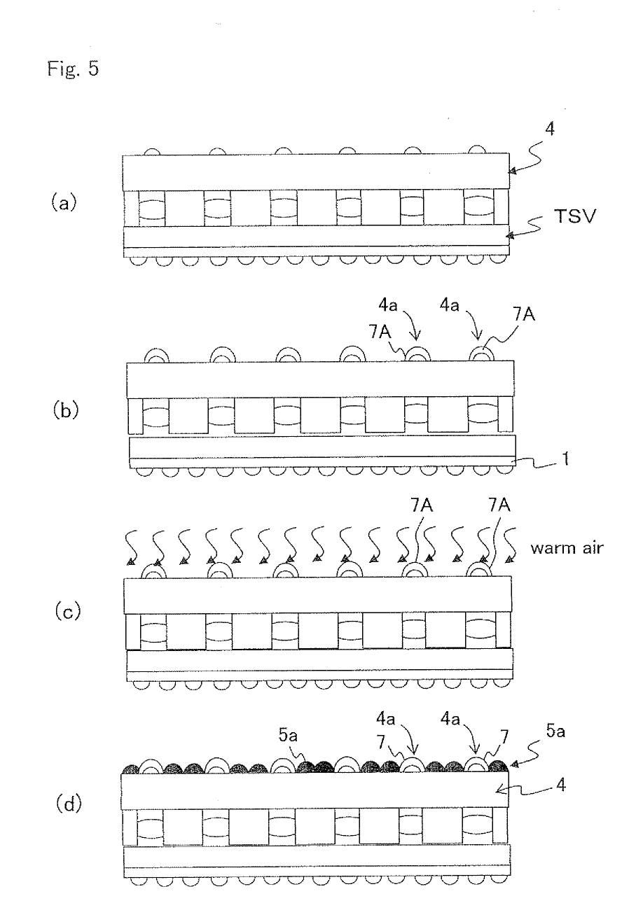

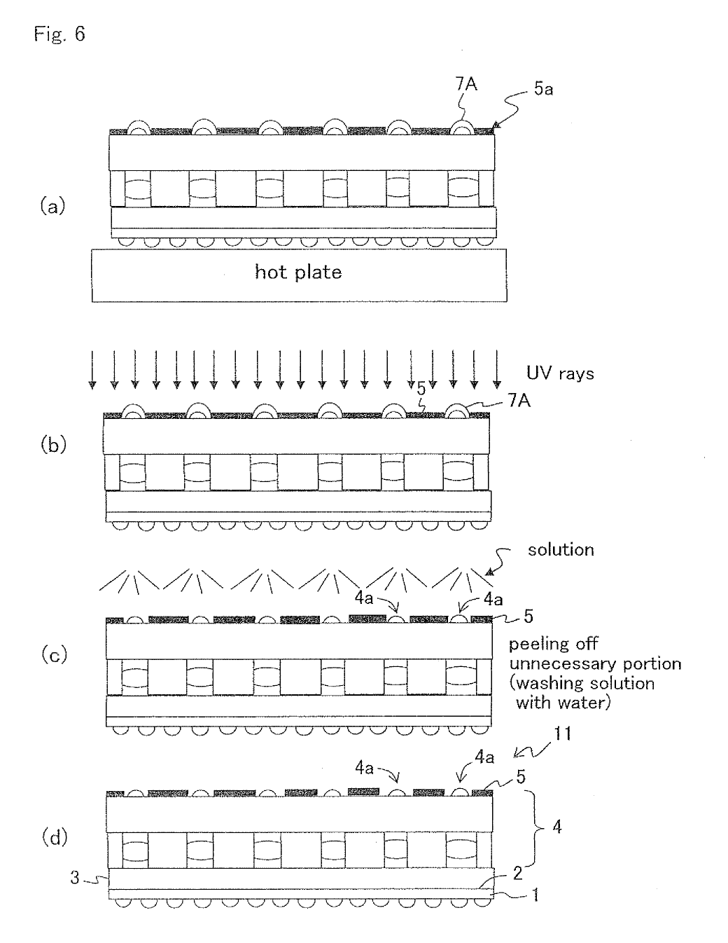

Hereinafter, another example of the method for manufacturing the sensor wafer module 11 with the structure described above will be described in detail with reference to FIGS. 5(a) to 5(d) and FIGS. 6(a) to 6(c).

First, a plurality of lens plates at the wafer level are laminated one above the other to form the lens wafer module 4, and the glass plate 3 is adhered to the sensor wafer 1 with the resin adhesion layer 2 one above the other to form a module TSV. Further, as illustrated in an adhering step of FIG. 5(a), the lens wafer module 4 is adhered on the module TSV with an alignment (positioning) such that the positions of the respective image capturing elements of the module TSV accurately correspond to the positions of the respective lenses of the lens wafer module 4.

Next, as illustrated in a protective resin forming step of FIG. 5(b), a soluble (water-soluble), protective resin film 7A is discharged from and formed by a dispenser (ink jet) with a high positional accuracy, only on the light openings 4a of the plurality of wafer-shaped image capturing elements of the sensor wafer 1. The protective resin film 7A may be formed such that etching process is performed using a photoresist film, which is patterned to a predetermined shape, as a mask, so that the protective resin film 7A remains accurately on only each of the light openings 4a of the respective image capturing elements. Further, a material which can be easily removed by water after being dissolved by a predetermined solution is used as the material of the protective resin film 7A.

Subsequently, as illustrated in a protective resin film warm air drying step of FIG. 5(c), the soluble protective resin film 7A, which is formed on only each of the respective light openings 4a corresponding to the plurality of wafer-shaped image capturing elements of the sensor wafer 1, is treated with warm air of a predetermined temperature (60° C. to 100° C., it is assumed to be 80° C. hereafter) for one hour to be dried and cured.

Next, as illustrated in a light shielding film forming step of FIG. 5(d), the light shielding material 5a is discharged and applied to cover the area other than the light openings 4a of the plurality of wafer-shaped image capturing elements of the sensor wafer 1 by a dispenser (ink jet) with a high positional accuracy.

Further, as illustrated in a light shielding film heating and extending step of FIG. 6(a), the lens wafer module 4, on which the light shielding material 5a is selectively applied, is mounted on a hot plate together with the module TSV and a heating process is performed (for thirty minutes at 120° C.). By the heating process, the discharged and applied light shielding material 5a is melted and extended so that the surface is planarized.

Further, as illustrated in a UV irradiating step of FIG. 6(b), ultraviolet rays (UV) are irradiated onto the heat-processed and melted light shielding material 5a to be cured so that the light shielding 5a is formed.

Further, as illustrated in an optical aperture forming step of FIG. 6(c), the soluble protective resin film 7A is dissolved by a predetermined solution (water or ethanol), and subsequently, the dissolved soluble protective resin film 7A is washed with water and removed to form an optical aperture structure by the light shielding film 5 at the light opening 4a of the lens area, as illustrated in FIG. 6(d).

According to the sensor wafer module 11 and the individualized sensor module 10 according to the present invention with the structure described above, the protective resin film 7 or 7A is provided with a high positional accuracy, so that, compared to an optical function module with the conventional mold structure, the high positional accuracy of the internal electronic elements (image capturing element 1a) as well as the high positioning accuracy between the internal electronic elements (image capturing element 1a) and the optical aperture structure of the optical element (lens) and the light shielding film 5 can be achieved, thereby obtaining a high manufacturing efficiency.

In addition, a significant improvement in the productivity and a cost reduction can be achieved by eliminating the application (molding) of the resin after the manufacturing of the optical element wafer module (lens wafer module 4) as is required in the conventional technique and by the simultaneous shielding by the light shielding film 5 on the upper surface of the optical element wafer module (lens wafer module 4) and the simultaneous manufacturing of a large number of optical aperture structures.

Further, a high positional discharging accuracy (positional error of a nozzle is ±10 μm to 20 μm; an appropriated amount of the protective resin is discharged from the nozzle) for at least the protective resin film 7 or 7A can be secured between the protective resin film 7 or 7A and the light shielding film material 5a by the dispenser (ink jet), and a significant reduction of the running costs can be achieved by the use of electronic devices with a fast signal processing speed. In a conventional screen printing, the positional error is ±50 μm or more. However, the discharging of the appropriate amount of the protective resin by the dispenser (ink jet) can be said to have a significant effect on the positional accuracy. If the optical aperture structure with the light shielding film 5 is dislodged with respect to the image capturing element, the feature of light receiving sensitivity is reduced, and as a result, an image maybe blurry or one side of a screen may be darker. However, such drawbacks can be prevented by the discharging of the appropriate amount of the protective resin.

Since the light shielding film 5 on the protective resin film 7 or 7A becomes thinner at an end portion of the lens, the peeling of the light shielding film 5 is easy. The higher the aspect ratio of the protective resin film 7 or 7A (film height/film's diameter on the lens), the more tapered and thinner the light shielding film 5 becomes at the end portion of the lens. Thus, the peeling including the light shielding film 5 (film thickness of about 80 μm) becomes easy. Therefore, the aspect ratio of the protective resin film 7 or 7A (film height (about 300 μm)/film's diameter on the lens (e.g., about 500 μm)) is set to between about 0.5 to 1.0. If the aspect ratio exceeds 1.0, the discharging rate is reduced due to the relationship with the viscosity of the protective resin film 7 or 7A.

Further, the electronic elements and optical elements are precisely positioned with a high positional accuracy, and the optical aperture structure together with the light shielding function of the light shielding film 5 for the electronic elements and optical elements are precisely positioned. Subsequently, mask forming and light shielding film forming are performed. As a result, the sensor wafer module 11 and the sensor module 10 can be manufactured with easy removal of the mask, a simple process, high performance, and at a low cost.

Although not specifically described in Embodiment 1, the light shielding film material 5a is, for example, acrylic resin containing carbon, and further, UV curing resin, which is cured by UV rays (irradiation with wavelength of 365 nm and energy of 4500 mJ for 20 to 30 minutes), or thermosetting resin.

### Embodiment 2

While Embodiment 1 describes the case where the lens wafer module 4 is laminated on the module TSV, and subsequently, the optical aperture is formed by the light shielding film 5 at each light opening 4a of the lens wafer module 4. Embodiment 2 describes the case where, instead of laminating the lens wafer module 4 on the module TSV, the optical aperture is formed by the light shielding film 5 at each light opening 4a of the lens wafer module 4, and subsequently, a lens wafer module 4A is laminated on the module TSV.

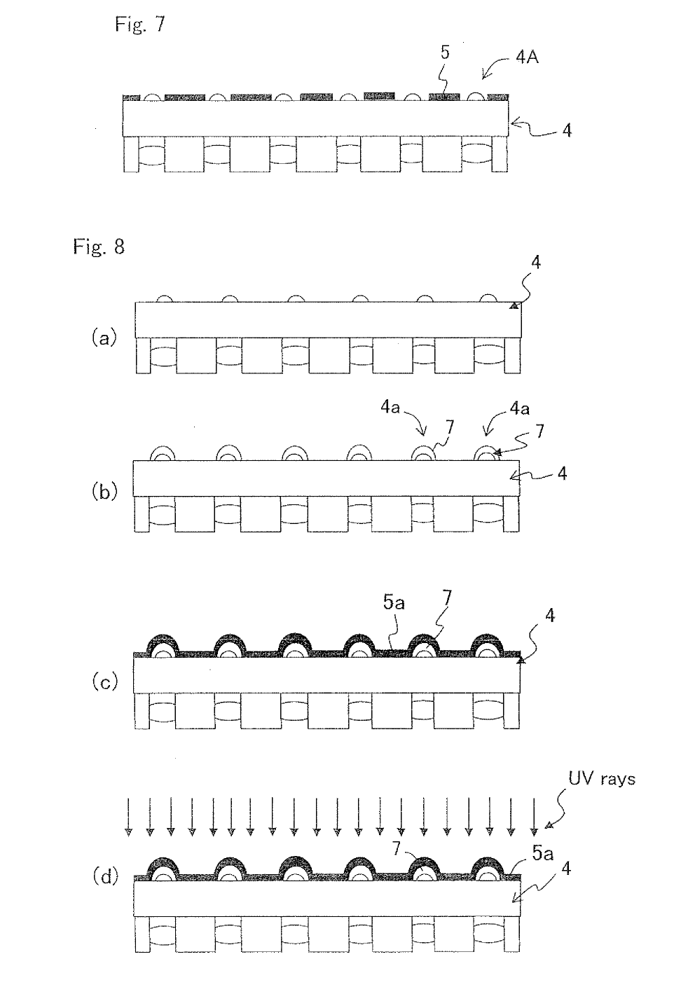

FIG. 7 is a longitudinal cross sectional view illustrating an exemplary essential part structure of a lens wafer module 4A according to Embodiment 2 of the present invention.

In FIG. 7, a lens wafer module 4A according to Embodiment 2 includes a lens wafer module 4, in which one or a plurality of lens plates are laminated as an optical element for focusing incident light on an image capturing element, and a light shielding film 5 formed in an area other than respective light openings 4a of a plurality of lenses of the lens wafer module 4.

Transparent resin lens plates constituting the lens wafer module 4 include, for example, an aberration correction lens plate 41, a diffusion lens plate 42, and a light focusing lens plate 43, and at least one plate is a light focusing lens plate.

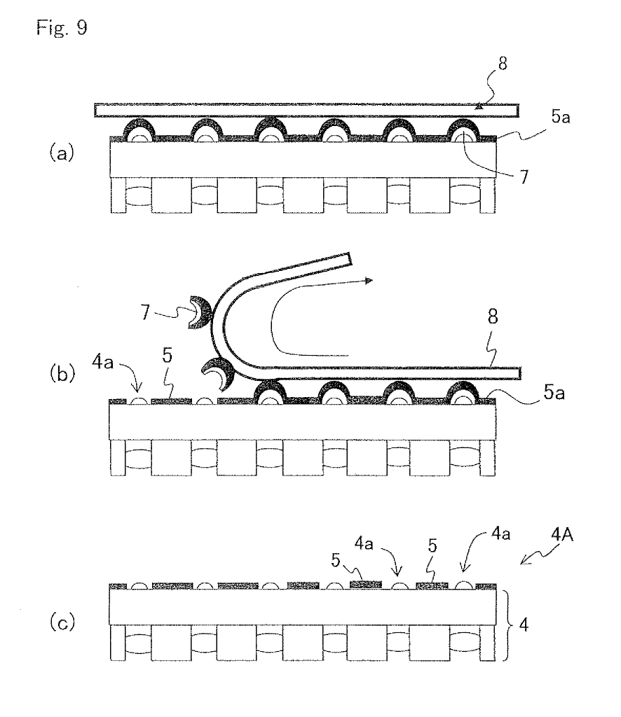

A method for manufacturing the lens wafer module 4A with the structure described above will be described in detail with reference to FIGS. 8(a) to 8(d) and FIGS. 9(a) to 9(c), where a plurality of lenses are positioned in a plane and a wafer shape and the light shielding film 5 is positioned thereon.

First, as illustrated in a laminating step of FIG. 8(a), a plurality of lens plates at a wafer level are laminated to form the lens wafer module 4. Further, the plurality of lens plates are aligned (positioned) at a wafer level successively such that the positions of the respective lenses precisely correspond to one another, and they are laminated one another with an adhesive.

Next, as illustrated in a protective resin forming step of FIG. 8(b), a low-viscosity protective resin film 7A is discharged and formed by a dispenser (ink jet) with a high positional accuracy on only the respective light openings 4a of the plurality of lenses. The protective resin film 7 maybe formed by an etching process performed using a photoresist film, which is patterned to a predetermined shape, as a mask. As a result, the protective resin film 7 remains accurately only on each of the light openings 4a of the respective image capturing elements. Further, the material for the protective resin film 7 may have a low viscosity with respect to the lens material (transparent resin or glass) for the lens wafer module 4, such that, in a later step, an adhesive tape can be peeled off both easily and securely together with the protective resin film 7 and a light shielding film 5a thereon, and further, the protective resin film 7 will not be dislodged or fall off from the lens surface.

Subsequently, as illustrated in a light shielding film forming step of FIG. 8(c), the light shielding material 5a is applied to cover the entire area including the light openings 4a of the plurality of wafer-shaped lenses for the formation of the light shielding material 5a.

Next, as illustrated in a UV irradiating step of FIG. 8(d), ultraviolet rays (UV) are irradiated onto the light shielding film material 5a, which is applied on the entire module, to be cured.

Further, as illustrated in an adhesive tape adhering step of FIG. 9(a), an adhesive tape 8 (peeling tape) is adhered on the light shielding material 5a on the protective resin film 7. In this case, the adhesive tape 8 is adhered to only the light shielding material 5a portion on the protective resin film 7 of the protruded lens surface (light opening 4a).

Further, as illustrated in an optical aperture forming step of FIG. 9(b), the adhesive tape 8 is peeled off together with the protective resin film 7 and the light shielding film material 5a on the protective resin film 7 to form the optical aperture by the light receiving film 5 at each circular light opening 4a of the lens area, as illustrated in FIG. 9(c).

As a result, the lens wafer module 4A according to Embodiment 2 can be manufactured.

The lens wafer module 4A is adhered on the module TSV such that the positions of the respective image capturing elements of the module TSV are aligned to precisely correspond to the positions of the respective lenses of the lens wafer module 4A. As a result, a sensor wafer module 11 according to Embodiment 2 can be manufactured. The sensor wafer module 11 at a wafer level is simultaneously cut and individualized, and subsequently, a light shielding member is provided on side surfaces thereof. As a result, a sensor module 10 (camera module) can be manufactured as each chip.

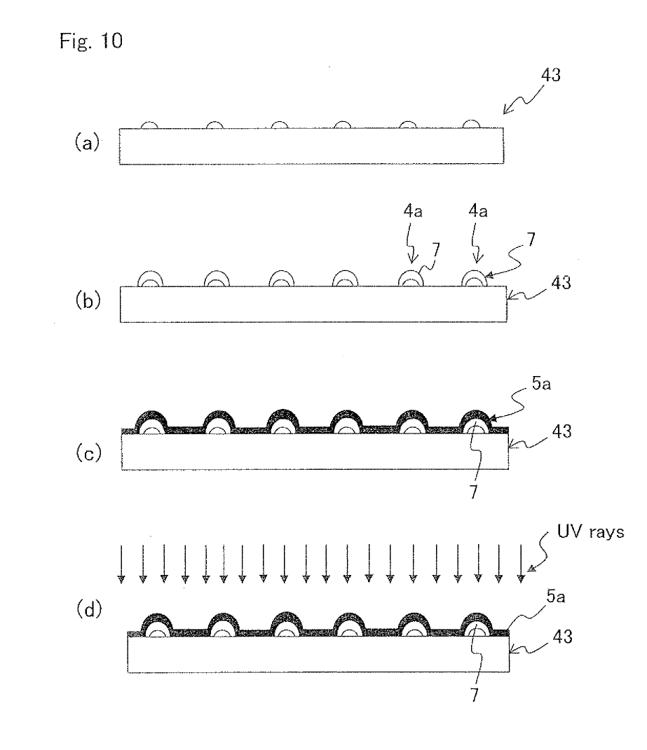

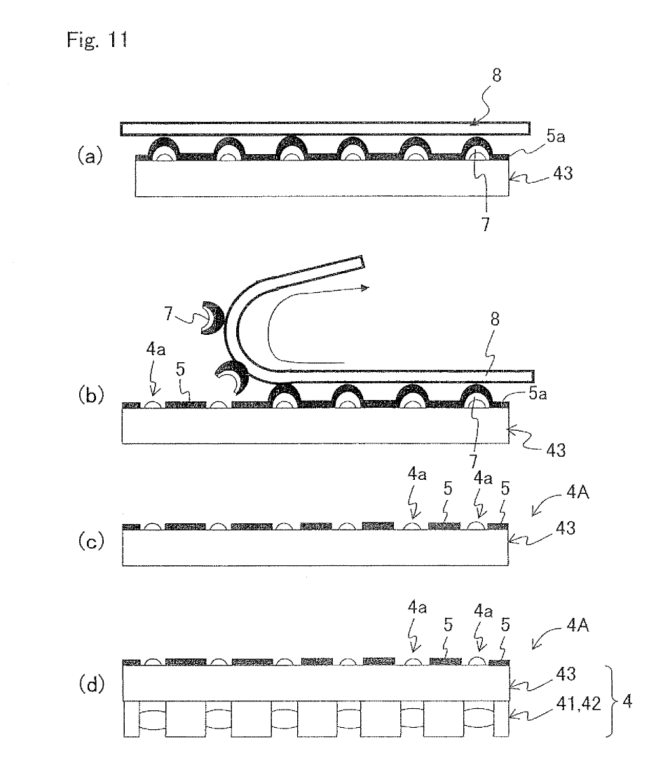

According to Embodiment 2 with the structure described above, the case has been described where, instead of laminating the lens wafer module 4 on the module TSV, the optical aperture is formed by the light shielding film 5 at each light opening 4a of the lens wafer module 4, and subsequently, the lens wafer module 4A including the light shielding film 5 formed thereon is laminated on the module TSV. However, without the limitation to this, as a variation of Embodiment 2, another case will be described in detail with reference to FIGS. 10(a) to 10(d) and FIGS. 11(a) to 11(d), where, instead of laminating a plurality of transparent resin lens plates (for example, three plates of an aberration correction lens plate 41, a diffusion lens plate 42, and a light focusing lens plate 43) to form the lens wafer module 4, an optical aperture is formed by the light shielding film 5 at each light opening 4a of the plurality of lenses of the upper most transparent resin lens plate, and subsequently, a plurality of transparent resin lens plates (for example, three plates of an aberration correction lens plate 41, a diffusion lens plate 42, and a light focusing lens plate 43) are laminated to form the lens wafer module 4.

First, as illustrated in a transparent resin lens plate setting step of FIG. 10(a), among a plurality of transparent resin lens plates (for example, three plates of an aberration correction lens plate 41, a diffusion lens plate 42, and a light focusing lens plate 43), the light focusing lens plate 43, which will be at the top when laminated, is prepared and set at a predetermined position.

Next, as illustrated in a protective resin forming step of FIG. 10(b), a low-viscosity, protective resin film 7 is discharged from and formed by a dispenser (ink jet) with a high positional accuracy, only on the light openings 4a of the plurality of light focusing lenses 43 arranged in two dimensions on the transparent resin lens plate. The protective resin film 7 may be formed by an etching process performed using a photoresist film, which is patterned to a predetermined shape, as a mask. As a result, the protective resin film 7 remains accurately only on each of the light openings 4a of the respective image capturing elements. Further, the material for the protective resin film 7 may have a low viscosity with respect to the lens material (transparent resin or glass) for the lens wafer module 4, such that, in a later step, an adhesive tape 8 can be peeled off both easily and securely together with the protective resin film 7 and a light shielding film 5a thereon, and further, the protective resin film 7 will be dislodged or fall off from the lens surface.

Subsequently, as illustrated in a light shielding film forming step of FIG. 10(c), the light shielding material 5a is applied to cover the entire area including the light openings 4a of the plurality of light focusing lenses 43 for the formation of the light shielding material 5a.

Next, as illustrated in a UV irradiating step of FIG. 10(d), ultraviolet rays (UV) are irradiated onto the light shielding film material 5a, which is applied on the entire module including the plurality of light focusing lenses 43 arranged in two dimensions on the transparent resin lens plate, to be cured.

Further, as illustrated in a adhesive tape adhering step of FIG. 11(a), an adhesive tape 8 (peeling tape) is adhered on the light shielding material 5a on the protective resin film 7. In this case, the adhesive tape 8 is adhered to only the light shielding material 5a portion on the protective resin film 7 of the protruded lens surface (light opening 4a).

Further, as illustrated in an optical aperture forming step of FIG. 11(b), the adhesive tape 8 is peeled off together with the protective resin film 7 and the light shielding film material 5a on the protective resin film 7 to form an optical aperture in the light receiving film 5 at each circular light opening 4a of the lens area of each of the plurality of light focusing lens plates 43, as illustrated in FIG. 11(c).

Further, as illustrated in a laminating step of FIG. 11(d), a plurality of transparent resin lens plates are laminated at a wafer level to form the lens wafer module 4A. Further, the plurality of transparent resin lens plates are aligned (positioned) at a wafer level such that the positions of the plurality of respective light focusing lenses precisely correspond to the positions of other transparent resin lens plates, and they are adhered together with an adhesive.

As a result, the lens wafer module 4A according to Embodiment 2 can be manufactured.

The lens wafer module 4A is adhered on the module TSV with an alignment (positioning) such that the positions of the respective image capturing elements of the module TSV accurately correspond to the positions of the respective lenses of the lens wafer module 4A. As a result, the sensor wafer module 11 according to Embodiment 2 can be manufactured. The sensor wafer module 11 at a wafer level is simultaneously cut and individualized, and subsequently, a light shielding member is provided on side surfaces thereof. As a result, a sensor module 10 (camera module) can be manufactured as each chip.

### Embodiment 3

While Embodiment 2 describes the case where, instead of laminating the lens wafer module 4 on the module TSV, the optical aperture is formed in the light shielding film 5 by peeling off the low-viscosity protective resin film 7 and the light shielding film 5 thereon on the light openings 4a of the lens wafer module 4, and subsequently, the lens wafer module 4A is laminated on the module TSV; Embodiment 3 describes the case where, prior to laminating the lens wafer module 4 on the module TSV, the soluble protective resin film 7A on the light openings 4a of the lens wafer module 4 is dissolved to be removed and the optical aperture is formed by the light shielding film 5, and subsequently, the lens wafer module 4 is laminated on the module TSV.

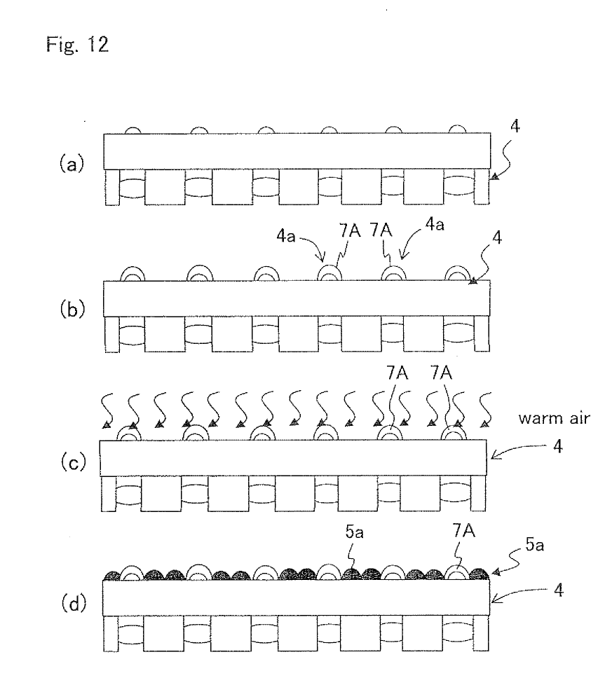

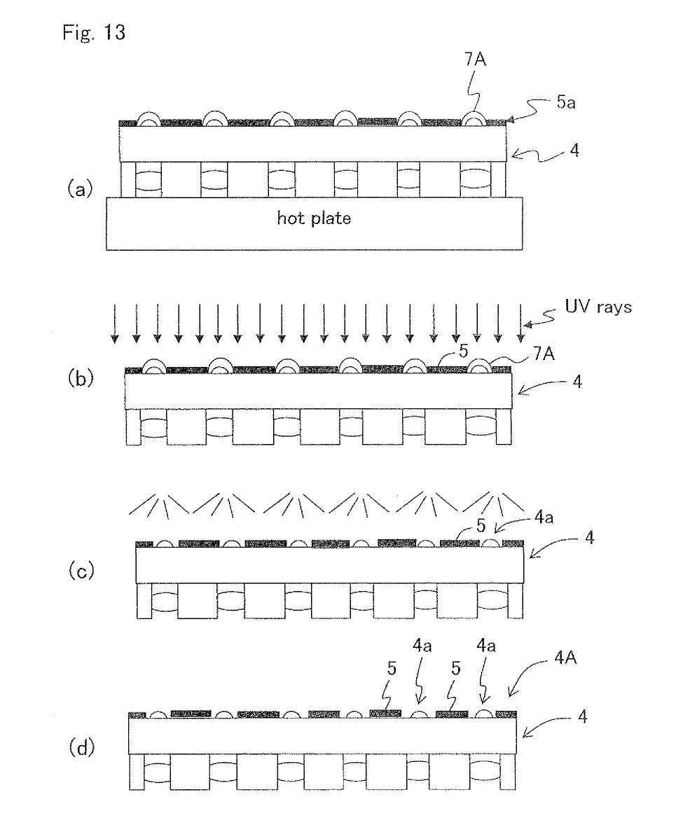

Another example of the method for manufacturing the lens wafer module 4A with the structure described above will be described in detail with reference to FIGS. 12(a) to 12(d) and FIGS. 13(a) to 13(d).

First, as illustrated in a laminating step of FIG. 12(a), a plurality of lens plates are laminated at a wafer level to form the lens wafer module 4. Further, the plurality of lens plates are aligned (positioned) successively at a wafer level such that the positions of the respective lenses precisely correspond to one another, and they are adhered together with an adhesive.

Next, as illustrated in a protective resin forming step of FIG. 12(b), a soluble protective resin film 7A is discharged and formed by a dispenser (ink jet) with a high positional accuracy on only the respective light openings 4a of the plurality of lenses. The protective resin film 7A may be formed by an etching process performed using a photoresist film, which is patterned to a predetermined shape, as a mask. As a result, the protective resin film 7A remains accurately only on each of the light openings 4a of the respective image capturing elements. Further, a material that is easily removed by water after being dissolved by a predetermined solution is used as the material of the protective resin film 7A.

Subsequently, as illustrated in a protective resin film warm air drying step of FIG. 12(c), the soluble protective resin film 7A, which is formed on only each of the respective light openings 4a of the lenses of the lens wafer module 4, is treated with warm air of a predetermined temperature to be dried and cured.

Subsequently, as illustrated in a light shielding film forming step of FIG. 12(d), the light shielding material 5a is discharged and applied to cover the area except for the light openings 4a of the lenses of the lens wafer module 4 by a dispenser (ink jet) with a high positional accuracy.

Further, as illustrated in a light shielding film heating and extending step of FIG. 13(a), the lens wafer module 4, on which the light shielding material 5a is selectively applied, is mounted on a hot plate and a heating process is performed thereon. By the heating process, the discharged and applied light shielding material 5a becomes melted and extended so that the surface is planarized.

Further, as illustrated in a UV irradiating step of FIG. 13(b), ultraviolet rays (UV) are irradiated onto the heat-processed and melted light shielding film material 5a to be cured, to form the light shielding film 5.

Further, as illustrated in an optical aperture forming step of FIG. 13(c), the protective resin film 7A is dissolved by a predetermined solution, and subsequently, the dissolved protective resin film 7A is washed away with water to form the optical aperture by the light shielding film 5 at the light openings 4a of the lens area, as illustrated in FIG. 13(d).

As a result, the lens wafer module 4A according to Embodiment 3 can be manufactured.

The lens wafer module 4A is adhered on the module TSV such that the positions of the respective image capturing elements of the module TSV are aligned to precisely correspond to the positions of the respective lenses of the lens wafer module 4A. As a result, a sensor wafer module 11 according to Embodiment 3 can be manufactured. The sensor wafer module 11 at a wafer level is simultaneously cut and individualized, and subsequently, a light shielding member is provided on side surfaces thereof. As a result, a sensor module 10 (camera module) can be manufactured as each chip.

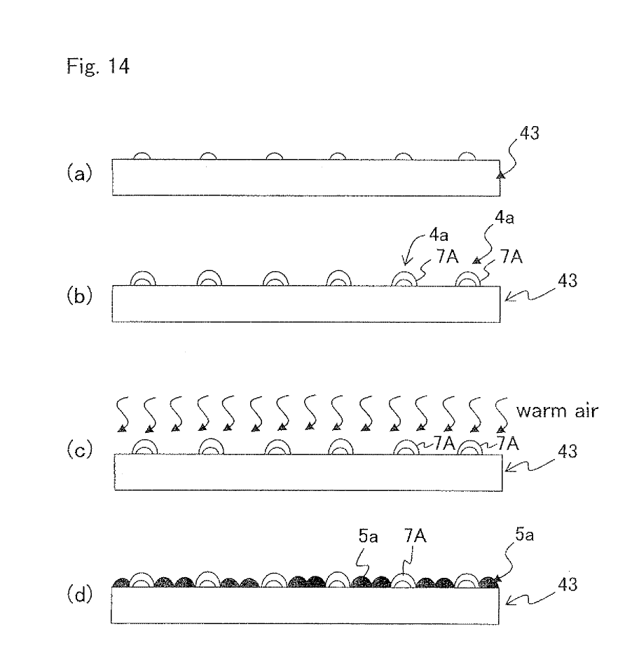

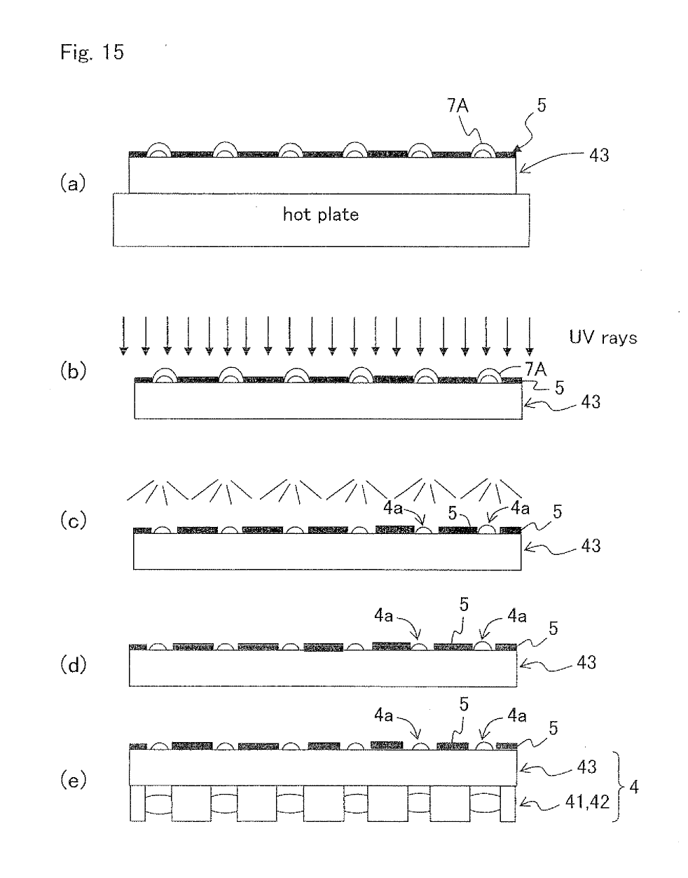

According to Embodiment 3 with the structure described above, the case has been described where, instead of laminating the lens wafer module 4 on the module TSV, the optical aperture is formed by the light shielding film 5 at each light opening 4a of the lens wafer module 4, and subsequently, the lens wafer module 4A provided with the light shielding film 5 is laminated on the module TSV. However, without the limitation to this, as a variation of Embodiment 3, another case will be described in detail with reference to FIGS. 14(a) to 14(d) and FIGS. 15(a) to 15(e), where, instead of laminating a plurality of transparent resin lens plates (for example, three plates of an aberration correction lens plate 41, a diffusion lens plate 42, and a light focusing lens plate 43) to form the lens wafer module 4, an optical aperture is formed by the light shielding film 5 at each light opening 4a of the plurality of lenses of the upper most transparent resin lens plate (the light focusing lens plate 43), and subsequently, a plurality of transparent resin lens plates (for example, three plates of an aberration correction lens plate 41, a diffusion lens plate 42, and a light focusing lens plate 43) are laminated to form the lens wafer module 4A.

FIGS. 14(a) to 14(d) and FIGS. 15(a) to 15(e) are each an essential part longitudinal cross sectional view of each manufacturing step for illustrating yet another example of the method for manufacturing the lens wafer module 4A of FIG. 7.

First, as illustrated in a transparent resin lens plate setting step of FIG. 14(a), among a plurality of transparent resin lens plates (for example, three plates of an aberration correction lens plate 41, a diffusion lens plate 42, and a light focusing lens plate 43), the light focusing lens plate 43, which will be the top transparent resin lens plate when laminated, is prepared and set at a predetermined position.

Next, as illustrated in a protective resin forming step of FIG. 14(b), a soluble protective resin film 7A is discharged from and formed by a dispenser (ink jet) with a high positional accuracy, only on the light openings 4a of the plurality of lenses arranged in two dimensions. The protective resin film 7A may be formed by an etching process performed using a photoresist film, which is patterned to a predetermined shape, as a mask. As a result, the protective resin film 7A remains accurately only on each of the light openings 4a of the plurality of lenses. Further, a material that is easily removed by water after being dissolved by a predetermined solution is used as the material of the protective resin film 7A.

Subsequently, as illustrated in a protective resin film warm air drying step of FIG. 14(c), the soluble protective resin film 7A, which is formed on only each of the respective light openings 4a of the lenses of the light focusing lens plate 43, is treated with warm air of a predetermined temperature to be dried and cured.

Subsequently, as illustrated in a light shielding film forming step of FIG. 14(d), the light shielding material 5a is discharged and applied to cover the area except for the light openings 4a of the lenses of the light focusing lens plate 43.

Further, as illustrated in a light shielding film heating and extending step of FIG. 15(a), the light focusing lens plate 43, on which the light shielding material 5a is selectively applied, is mounted on a hot plate and a heating process is performed thereon. By the heating process, the discharged and applied light shielding material 5a is melted and extended so that the surface is planarized.

Further, as illustrated in a UV irradiating step of FIG. 15(b), ultraviolet rays (UV) are irradiated onto the heat-processed and melted light shielding film material 5a to be cured, to form the light shielding film 5.

Further, as illustrated in an optical aperture forming step of FIG. 15(c), the protective resin film 7A is dissolved by a predetermined solution, and subsequently, the dissolved protective resin film 7A is washed away with water to form the optical aperture in the light shielding film 5 at the light openings 4a of the lens area, as illustrated in FIG. 15(d).

Further, as illustrated in a laminating step of FIG. 15(e), the plurality of transparent resin lens plates at a wafer level are laminated to form the lens wafer module 4A. Further, the plurality of transparent resin lens plates are aligned (positioned) at a wafer level such that the positions of the plurality of respective light focusing lenses 43 precisely correspond to the positions of the lenses of other transparent resin lens plates, and they are laminated together with an adhesive.

As a result, the lens wafer module 4A according to Embodiment 3 can be manufactured.

The lens wafer module 4A is adhered on the module TSV such that the positions of the respective image capturing elements of the module TSV are aligned to precisely correspond to the positions of the respective lenses of the lens wafer module 4A. As a result, a sensor wafer module 11 at a wafer level according to Embodiment 3 can be manufactured. The sensor wafer module 11 is simultaneously cut and individualized, and subsequently, a light shielding member is provided on side surfaces thereof. As a result, a sensor module 10 (camera module) can be manufactured as each chip.

### Embodiment 4

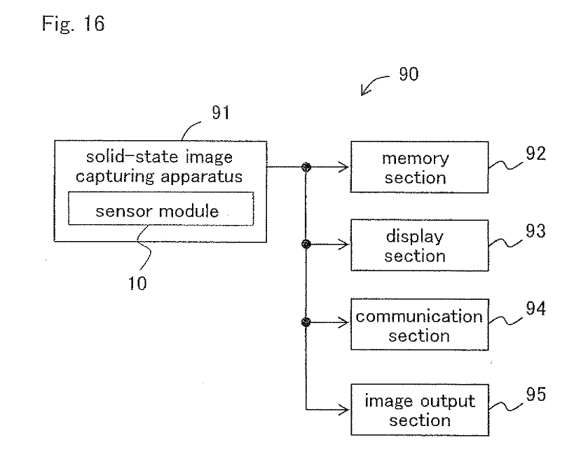

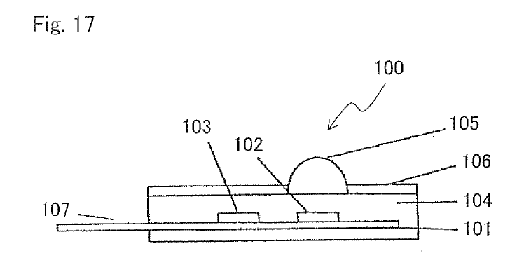

FIG. 16 is a block diagram schematically illustrating an exemplary schematic structure of an electronic information device as Embodiment 4 of the present invention, including the sensor module 10 according to any of Embodiments 1 to 3 of the present invention used in an image capturing section thereof.

In FIG. 16, an electronic information device 90 according to Embodiment 4 of the present invention includes: a solid-state image capturing apparatus 91 for performing various signal processing on an image capturing signal from the sensor module 10 according to any of Embodiments 1 to 3 so as to obtain a color image signal; a memory section 92 (e.g., recording media) for data-recording a color image signal from the solid-state image capturing apparatus 91 after a predetermined signal processing is performed on the color image signal for recording; a display section 93 (e.g., a liquid crystal display apparatus) for displaying the color image signal from the solid-state image capturing apparatus 91 on a display screen (e.g., liquid crystal display screen) after predetermined signal processing is performed on the color image signal for display; a communication section 94 (e.g., a transmitting and receiving device) for communicating the color image signal from the solid-state image capturing apparatus 91 after predetermined signal processing is performed on the color image signal for communication; and an image output section 95 (e.g., a printer) for printing the color image signal from the solid-state image capturing apparatus 91 after predetermined signal processing is performed for printing. Without any limitations to this, the electronic information device 90 may include any of the memory section 92, the display section 93, the communication section 94, and the image output section 95, other than the solid-state image capturing apparatus 91.

As the electronic information device 90, an electronic device that includes an image input device is conceivable, such as a digital camera (e.g., digital video camera or digital still camera), an image input camera (e.g., a monitoring camera, a door phone camera, a camera equipped in a vehicle as a car-mounted back view monitoring camera, or a television camera), a scanner, a facsimile machine, a camera-equipped cell phone device or a personal digital assistant (PDA).

Therefore, according to Embodiment 4 of the present invention, the color image signal from the solid-state image capturing apparatus 91 can be: displayed on a display screen properly by the display section 93, printed out on a sheet of paper using an image output section 95, communicated properly as communication data via a wire or a radio by the communication section 94, stored properly at the memory section 92 by performing predetermined data compression processing; and various data processes can be properly performed.

Without the limitation to the electronic information device 90 according to Embodiment 4, the electronic information device may be a pick up apparatus including the electronic element module of the present invention used in an information recording and reproducing section thereof. In this case, the optical element of the pick up apparatus is an optical function element (for example, a hologram optical element) for directing output light straight to be output and refracting and guiding incident light in a predetermined direction. In addition, as the electronic element of the pick up apparatus, a light emitting element for emitting output light (for example, a semiconductor laser element or laser chip) and a light receiving element for receiving incident light (for example, a photo IC) are included.

In Embodiments 1 to 4, the case has been described where the optical element is a lens and the electronic element is an image capturing element including a plurality of light receiving sections for performing a photoelectric conversion on and capturing an image of image light from a subject. Without the limitation to this, the optical element may also be a prism or an optical function element for directing output light straight to be output and refracting and guiding incident light in a predetermined direction. In addition, as described above, the electronic element may also be a light emitting element for emitting output light and a light receiving element for receiving incident light.

Although not specifically described in Embodiments 1 to 3, the method for manufacturing the electronic element wafer module 11 according to the present invention includes: a protective resin film forming step for forming a protective resin film 7 or 7A on only light openings 4a of a plurality of wafer-shaped optical elements; a light shielding film forming step of filming a light shielding film material 5a on an area except for the light openings 4a or an entire area including the light openings 4a; and an optical aperture forming step of removing the protective resin film 7 or 7A, or removing the protective resin film 7 or 7A and the light shielding film material 5a on the protective resin film 7 or 7A to form an optical aperture by the light shielding film 5 at the light openings 4a.

The protective resin film 7 or 7A is discharged with a high positional accuracy by a dispenser, and the protective resin film 7 or 7A is removed after the light shielding film 5 is formed based on discharging. Therefore, compared to the optical function module of the conventional mould structure, it becomes possible to achieve the objective of the present invention, which is a high positional accuracy of the internal electronic elements and a high positioning accuracy between the internal electronic elements and the optical aperture structure of the optical element and the light shielding film 5 as well as a high manufacturing efficiency.

As described above, the present invention is exemplified by the use of its preferred Embodiments 1 to 4. However, the present invention should not be interpreted solely based on Embodiments 1 to 4 described above. It is understood that the scope of the present invention should be interpreted solely based on the claims. It is also understood that those skilled in the art can implement equivalent scope of technology, based on the description of the present invention and common knowledge from the description of the detailed preferred Embodiments 1 to 4 of the present invention. Furthermore, it is understood that any patent, any patent application and any references cited in the present specification should be incorporated by reference in the present specification in the same manner as the contents are specifically described therein.

### INDUSTRIAL APPLICABILITY

The present invention can be applied in the field of: an electronic element wafer module with an optical aperture structure and a method for manufacturing the electronic element wafer module; an optical element wafer module used for the electrical element wafer module and a method for manufacturing the optical element wafer module; an electronic element module individualized by simultaneously cutting the electronic element wafer module; and an electronic information device, such as a digital camera (e.g., a digital video camera or a digital still camera), an image input camera (e.g., a monitoring camera), a scanner, a facsimile machine, a television telephone apparatus and a camera-equipped cell phone device, including the electronic element module as an image input device used in an image capturing section thereof. According to the present invention, compared to the optical function module of the conventional mould structure, it becomes possible to achieve a high positional accuracy of the internal electronic elements themselves and a high positioning accuracy between the internal electronic elements and the optical aperture structure of the optical element and the light shielding film 5 as well as a high manufacturing efficiency.

Further, a significant improvement on the productivity and a cost reduction can be achieved by eliminating the application (molding) of the resin after the manufacturing of the optical element wafer module as is required in the conventional technique and by the simultaneous shielding by the light shielding film on the upper surface of the optical element wafer module and the simultaneous manufacturing of a large number of optical aperture structures.

Further, a drastic reduction of the accumulative cost can be achieved by securing a high positional accuracy of the discharging of a light shielding film material by ink jet or the like and by the use of a device with fast signal processing.

Further, by precisely positioning the electronic elements and the optical elements with a high positional accuracy, by precisely positioning the optical aperture structure with an accuracy together with the light shielding function with respect to the electronic elements and the light shielding film and by manufacturing a mask and the light shielding film at a high speed, it becomes possible to remove the mask easily and to perform the manufacturing with a simple process and at a low cost.

Various other modifications will be apparent to and can be readily made by those skilled in the art without departing from the scope and spirit of this invention. Accordingly, it is not intended that the scope of the claims appended hereto be limited to the description as set forth herein, but rather that the claims be broadly construed.

What is claimed is:

1. A method for manufacturing an electronic element wafer module in which a plurality of optical elements of at least one wafer shape are positioned on an electronic element wafer with a plurality of electronic elements formed therein, such that the plurality of optical elements face the plurality of respective electronic elements, the method comprising:
a protective resin film forming step of forming a protective resin film on only light openings of the plurality of wafer-shaped optical elements;
a light shielding film forming step of filming a light shielding film on an area except for the light openings or an entire area including the light openings ; and
an optical aperture forming step of removing the protective resin film, or removing the protective resin film and a light shielding film material on the protective resin film, to form an optical aperture structure in the light shielding film at the light openings.

2. A method for manufacturing an electronic element wafer module according to claim 1, wherein the optical aperture forming step includes:
an adhesive tape adhering step of adhering an adhesive tape on the light shielding film on the protective resin film; and
an adhesive tape peeling step of peeling off the adhesive tape together with the protective resin film and the light shielding film on the protective resin film.

3. A method for manufacturing an electronic element wafer module according to claim 1, wherein the optical aperture forming step includes a protective resin film removing step of dissolving and removing the protective resin film with a solution.

4. A method for manufacturing an electronic element wafer module according to claim 1, wherein the protective resin film is either a protective resin film having viscosity lower than viscosity of the light shielding film or a soluble protective resin film.

5. A method for manufacturing an electronic element wafer module according to claim 1, wherein, in the protective resin film forming step, a material of the protective resin film to be formed is discharged by a dispenser.

6. A method for manufacturing an electronic element wafer module according to claim 1, wherein, in the protective resin film forming step, an etching process is performed using a photoresist film, which is patterned to a predetermined shape, as a mask, to leave the protective resin film on only the light openings.

7. A method for manufacturing an electronic element wafer module according to claim 4, wherein a material capable of being dissolved with water or ethanol as a predetermined solution and being removed by washing with water is used for the soluble protective resin film.

8. A method for manufacturing an electronic element wafer module according to claim 1, wherein a film thickness/a plan view diameter is set between 0.5 and 1.0 as the aspect ratio of the protective resin film.

9. A method for manufacturing an electronic element wafer module according to claim 1, wherein the light shielding film uses, as a material, any of acrylic resin, epoxy resin, ABS resin, PP resin and PC resin.

10. A method for manufacturing an electronic element wafer module according to claim 1, wherein the material of the light shielding film contains carbon.

11. A method for manufacturing an electronic element wafer module according to claim 9, wherein the material of the light shielding film contains carbon.

12. A method for manufacturing an electronic element wafer module according to claim 1, wherein the material of the light shielding film is either UV curing resin or thermosetting resin.

13. A method for manufacturing an electronic element wafer module according to claim 1, wherein a transparent support substrate is positioned on the electronic element wafer, and the plurality of optical elements of at least one wafer shape are positioned on the transparent support substrate.

14. A method for manufacturing an electronic element wafer module according to claim 1, wherein the plurality of wafer-shaped optical elements are adhered on the electronic element wafer with the plurality of electronic elements formed therein, and subsequently, the protective resin film forming step, the light shielding film forming step, and the optical aperture forming step are performed.

15. A method for manufacturing an electronic element wafer module according to claim 1, wherein an optical element wafer module is formed, in which the plurality of optical element wafers with the optical elements arranged in two dimensions therein are laminated to one another, and subsequently, the protective resin film forming step, the light shielding film forming step, and the optical aperture forming step are performed for the optical element wafer module, and further, the optical element wafer module, on which the optical aperture structure is formed, is adhered on the electronic element wafer with the plurality of electronic elements formed therein.

16. A method for manufacturing an electronic element wafer module according to claim 1, wherein the protective resin film forming step, the light shielding film forming step, and the optical aperture forming step are performed for the optical element wafer on which the plurality of optical elements are arranged in two dimensions, and subsequently, in such a manner that the optical element wafer is arranged to the upper most position the plurality of optical element wafers, on which the plurality of optical elements are arranged in two dimensions, are laminated to form an optical element wafer module, and further, the optical element wafer module is adhered on the electronic element wafer with the plurality of electronic elements formed therein.

17. A method for manufacturing an optical element wafer module, on which a plurality of optical element wafers with a plurality of optical elements arranged in two dimensions therein are laminated, the method comprising:
a protective resin film forming step of forming a protective resin film on only light openings of the plurality of wafer-shaped optical elements;
a light shielding film forming step of filming a light shielding film on an area except for the light openings or an entire area including the light openings; and
an optical aperture forming step of removing the protective resin film, or removing the protective resin film and a light shielding film material on the protective resin film, to form an optical aperture structure in the light shielding film at the light openings.

18. A method for manufacturing an optical element wafer module according to claim 17, wherein the optical aperture forming step includes:
an adhesive tape adhering step of adhering an adhesive tape on the light shielding film on the protective resin film; and
an adhesive tape peeling step of peeling off the adhesive tape together with the protective resin film and the light shielding film on the protective resin film to form optical apertures at the respective light openings.

19. A method for manufacturing an optical element wafer module according to claim 17, wherein the optical aperture forming step includes a protective resin film removing step of dissolving and removing the protective resin film with a solution.

20. A method for manufacturing an optical element wafer module according to claim 17, wherein the protective resin film forming step, the light shielding film forming step, and the optical aperture forming step are performed for the optical element wafer module, in which the plurality of optical element wafers with the plurality of optical elements formed in two dimensions therein are laminated.

21. A method for manufacturing an optical element wafer module according to claim 17, wherein the protective resin film forming step, the light shielding film forming step, and the optical aperture forming step are performed for the optical element wafer with the plurality of optical elements formed in two dimensions therein, and subsequently, in such a manner that the optical element wafer is arranged to the upper most position, the plurality of optical element wafers, on which the plurality of optical elements are arranged in two dimensions, are laminated to form an optical element wafer module.

22. An electronic element wafer module manufactured by any of the methods for manufacturing the electronic element wafer module according to claim 1,
wherein:
the optical element is either a lens or a prism; and
the electronic element is an image capturing element including a plurality of light receiving sections for performing a photoelectric conversion on and capturing an image of image light from a subject.

23. An electronic element wafer module manufactured by any of the methods for manufacturing the electronic element wafer module according to claim 1,
wherein:
the optical element is an optical function element for directing output light straight to be output and refracting and guiding incident light in a predetermined direction; and
the electronic element is alight emitting element for emitting output light and a light receiving element for receiving incident light.

24. An electronic element module which is cut and individualized from the electronic element wafer module according to claim 22, for every one or the plurality of electronic element modules.

25. An electronic element module which is cut and individualized from the electronic element wafer module according to claim 23, for every one or the plurality of electronic element modules.

26. An optical element wafer module manufactured by any of the methods for manufacturing the optical element wafer module according to claim 17, wherein the optical element is either a lens or a prism.

27. An optical element wafer module manufactured by any of the methods for manufacturing the optical element wafer module according to claim 17, wherein the optical element is an optical function element for directing output light straight to be output and refracting and guiding incident light in a predetermined direction.

28. An electronic information device including the electronic element module according to claim 24 used as an image input device in an image capturing section.

29. An electronic information device including the electronic element module according to claim 25 used as an image input device in an information recording and reproducing device.
